(19) United States
(12) Patent Application Publication
(10) Pub. No.: US 2016/0071568 A1
(43) Pub. Date: Mar. 10, 2016

(54) SEMICONDUCTOR MEMORY DEVICE

(71) Applicants: Shintaro SAKAI, Seoul (KR); Hiromi NORO, Seoul (KR)

(72) Inventors: Shintaro SAKAI, Seoul (KR); Hiromi NORO, Seoul (KR)

(21) Appl. No.: 14/644,066

(22) Filed: Mar. 10, 2015

Related U.S. Application Data
(60) Provisional application No. 62/047,522, filed on Sep. 8, 2014.

(51) Int. Cl. G11C 11/16

(52) U.S. Cl. CPC G11C 11/1675

(57) ABSTRACT

A semiconductor memory device includes a first pad which outputs data to the outside; an output driver coupled to the first pad; a calibration circuit which adjusts impedance of the output driver; and a controller. The controller controls a calibration operation by the calibration circuit, in response to a first command received from the outside, and performs a write operation on a mode resister, in response to a second command received from the outside, the second command being different from the first command.

### CROSS-REFERENCE TO RELATED APPLICATIONS

This application claims the benefit of U.S. Provisional Application No. 62/047,522, filed Sep. 8, 2014, the entire contents of which are incorporated herein by reference.

### FIELD

Embodiments described herein relate generally to a semiconductor memory device.

### BACKGROUND

A resistance-change memory is known as one type of semiconductor memory device. As one type of resistance-change memory, a magnetoresistive random access memory (MRAM) is known in the art. The MRAM is a memory device that comprises magnetoresistive elements utilizing the magnetoresistive effect. It attracts much attention as a next-generation memory device that is nonvolatile, operates at high speed and has a large capacity. The MRAM is being researched and developed as a replacement for volatile memories such as a DRAM and an SRAM.

The MRAM, expected to serve many uses, may be used in various conditions. It may be used at high frequency to operate at a high speed. If the MRAM is used at high frequency, the data output driver must be adjusted to have optimal drive efficiency.

### BRIEF DESCRIPTION OF THE DRAWINGS

FIG. 1 is a block diagram of a semiconductor memory device according to an embodiment;

FIG. 2 is a block diagram of each bank;

FIG. 3 is a block diagram of an upper peripheral circuit shown in FIG. 1;

FIG. 4 is a block diagram of a lower peripheral circuit shown in FIG. 1;

FIG. 5 is a circuit diagram of a memory cell array provided in each bank;

FIG. 6 is a sectional view of an MTJ element;

FIG. 7 is a circuit diagram of a ZQ calibration circuit;

FIG. 8 is a block diagram of an output driver;

FIG. 9 is a diagram illustrating the relation between an output impedance of the output driver and selection signals;

FIG. 10 is a state diagram of the semiconductor memory device;

FIG. 11 is a timing chart of the ZQ calibration operation according to the embodiment; and

FIG. 12 is a timing chart of the ZQ calibration operation according to a comparative example.

### DETAILED DESCRIPTION

In general, according to one embodiment, there is provided a semiconductor memory device comprising:

a first pad which outputs data to the outside;

an output driver coupled to the first pad;

a calibration circuit which adjusts impedance of the output driver; and

a controller which

controls a calibration operation by the calibration circuit, in response to a first command received from the outside, and

performs a write operation on a mode resister, in response to a second command received from the outside, the second command being different from the first command.

Embodiments will be described hereinafter with reference to the accompanying drawings. In the description below, structural elements having substantially identical functions and structures are denoted by like reference numerals, and an overlapping description will be given only where necessary. The drawings are schematic ones. Each embodiment illustrates a device or a method for embodying the technical concept of the embodiment, and the technical concept of the embodiment does not restrict the materials, shapes, structures, dispositions, etc. of the structural elements to those described below.

The embodiment described below is, for example, a magnetoresistive random access memory (MRAM) that is one type of resistance-change memory.

### [1] Configuration of the Semiconductor Memory Device

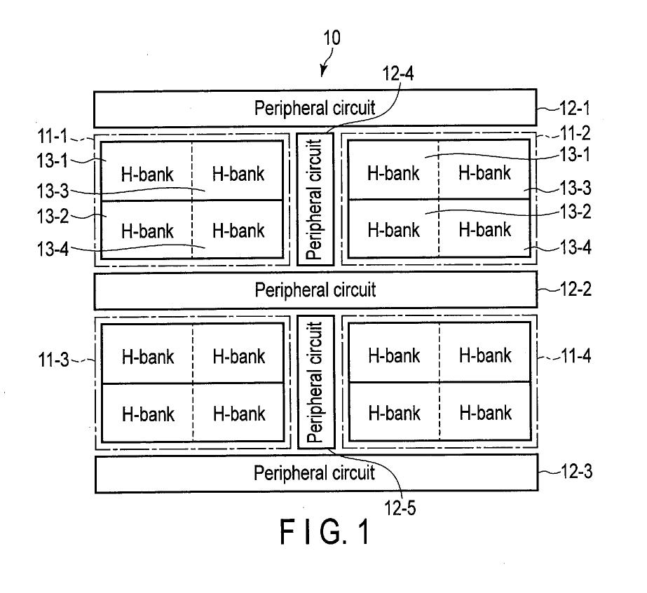

FIG. 1 is a block diagram of a semiconductor memory device 10 according to the embodiment. The semiconductor memory device (i.e., MRAM) 10 comprises a plurality of memory core circuits 11, and a plurality of peripheral circuits 12 (12-1 to 12-5) provided around the memory core circuits 11. In FIG. 1, four memory core circuits 11-1 to 11-4, for example, are illustrated. Incidentally, in the description of the present embodiment, when there is no need to distinguish the plural memory core circuits 11-1 to 11-4, the memory core circuit is described with the reference numeral without the suffix number, and the description of this memory circuit corresponds to the description of each of the plural memory core circuits 11-1 to 11-4. As regards the other reference numerals with suffix numbers, the same as in the case of memory core circuits 11 applies.

Each memory core circuit 11 comprises, for example, four half banks (H-banks) 13-1 to 13-4. The first bank, for example, comprises the half bank 13-1 included in the memory core circuit 11-1 and the half bank 13-1 included in the memory core circuit 11-2. Similarly, the second to fourth banks comprise the half banks 13-2 to 13-4 included in the memory core circuit 11-1 and the half banks 13-2 to 13-4 included in the memory core circuit 11-2, respectively. Incidentally, the definitions and assignments of the banks can arbitrarily be set.

[1-1] Configuration of the Bank 100

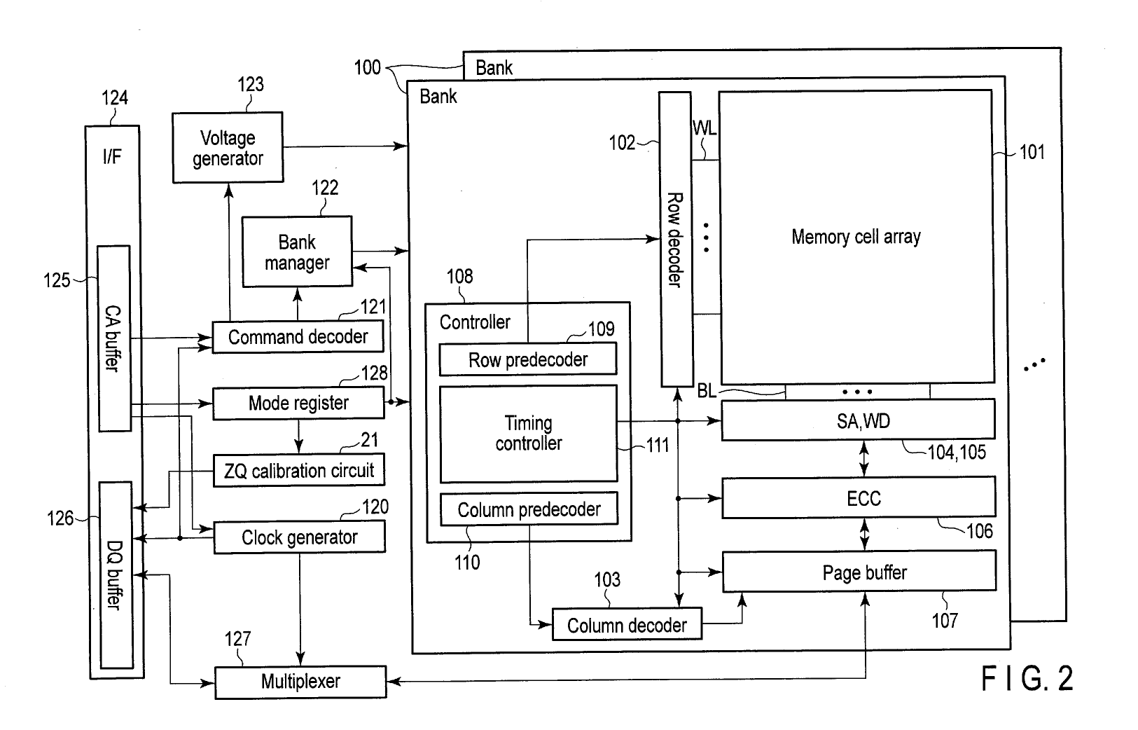

Next, the configuration of the bank 100 is described. FIG. 2 is a block diagram of the bank 100. The bank 100 comprises a memory cell array 101, a row decoder 102, a column decoder 103, a sense amplifier (SA) 104, a write driver (WD) 105, an error check and correcting (ECC) circuit 106, a page buffer 107 and a controller 108.

The memory cell array 101 comprises a plurality of memory cells arranged in a matrix. Each of the plurality of memory cells comprises a magnetoresistive effect element.

The row decoder 102 decodes a row address and selects one of the rows of the memory cell array 101, based on the decode result. The column decoder 103 decodes a column address and selects one of the columns of the memory cell array 101, based on the decode result.

The sense amplifier (read circuit) 104 detects and amplifies the data stored in the memory cells through the bit lines arranged in the memory cell array 101. The write driver 105 (write circuit) writes the data from an interface circuit (input/output circuit) 124 to the memory cells through the bit lines.

The ECC circuit 106 generates an error correction code by using the write data in writing data. The error correction code is written to the memory cell array 101, together with the write data. The ECC circuit 106 corrects the error of the read data by using the error correction code contained in the read data in reading data. The error correction code is removed from the read data.

The page buffer (data buffer) 107 temporarily holds the write data sent from the interface circuit 124 in writing data. The page buffer 107 temporarily holds the read data sent from the memory cell array 101 in reading data.

The controller 108 generally controls each circuit in the bank 100. The controller 108 comprises a row predecoder 109, a column predecoder 110, and a timing controller 111. The timing controller 111 controls the operating timing of each circuit in the bank 100.

The row predecoder 109 pre-decodes the row address, for example, included by the address sent from a bank manager 122. The column predecoder 110 pre-decodes the column address, for example, included by the address sent from the bank manager 122.

The peripheral circuit 12 shown in FIG. 1 comprises a clock generator 120, a command decoder 121, a bank manager 122, a voltage generator 123, an interface circuit 124, a multiplexer 127, a mode register 128, and a ZQ calibration circuit 21, all shown in FIG. 2.

The interface circuit 124 sends and receives the data and control signals (including commands and statuses) between an external device (e.g., memory controller or host device). The interface circuit 124 comprises a CA buffer 125 and a DQ buffer 126. The CA buffer 125 receives a command/address, a clock enable signal, a bank select signal, an external clock signal, and others all from the external device. The DQ buffer 126 sends and receives a data input/output signal (i.e., data), a data strobe signal, a data mask signal, and others.

The clock generator 120 generates an internal clock signal of the semiconductor memory device 10, based on the clock enable signal and external clock signal from the CA buffer 125. The generated internal clock signal is supplied to each circuit in the semiconductor memory device 10. At the timing based on the internal clock signal generated by the clock generator 120, some other circuits operate in the semiconductor memory device 10.

The command decoder 121 decodes any command sent from the CA buffer 125. The decoded command is sent to the bank manager 122 and voltage generator 123.

The bank manager 122 sends various kinds of information such as the addresses in the memory cell array 101, and control signals for each circuit in the bank 100 to the bank 100 selected by the bank select signal, to execute the operation corresponding to the command/address.

The voltage generator 123 generates various voltages for use in the operation corresponding to any commands. The generated voltage is applied to specified circuits in the bank 100.

The multiplexer 127 controls the timing of transferring the data between the bank 100 and the DQ buffer 126 at the timing based on the internal clock signal.

The mode register 128 stores the data for setting the operating mode of the semiconductor memory device 10.

[1-2] Configuration of the Peripheral Circuits 12

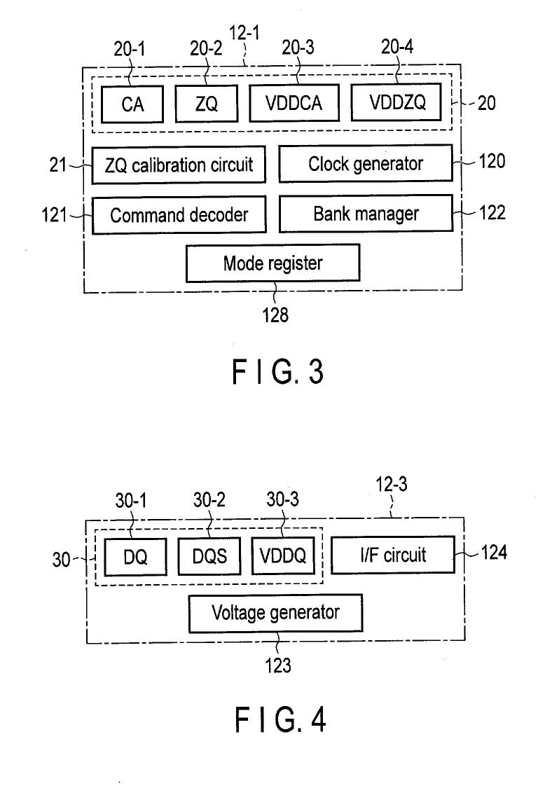

Next, an example of the configuration of the periphery circuits 12 (i.e., circuits 12-1 to 12-5) is described. FIG. 3 is a block diagram of the peripheral circuit 12-1 shown in FIG. 1. The peripheral circuit 12-1 comprises a pad unit 20, a ZQ calibration circuit 21, a clock generator 120, a command decoder 121, a bank manager 122, a mode register 128, and others.

The pad unit 20 comprises a command/address (CA) pad 20-1, a calibration pad (ZQ pad) 20-2, a VDDCA pad 20-3, a VDDZQ pad 20-4, and others. The CA pad 20-1 is used to input/output commands and addresses from/to the outside. The ZQ pad 20-2 is used while the ZQ calibration circuit 21 is operating. The VDDCA pad 20-3 receives power-supply VDDCA for each circuit controlling command and address, from the outside. The VDDZQ pad 20-4 receives a power-supply VDDZQ for the ZQ calibration circuit 21 from the outside.

The ZQ calibration circuit 21 automatically adjusts the output impedance (i.e., drive strength) of a data output driver. Variations of the output impedance due to the process, voltage and temperature are compensated by the ZQ calibration. The configuration of the ZQ calibration circuit 21 will be described later.

FIG. 4 is a block diagram of the peripheral circuit 12-3 shown in FIG. 1. The peripheral circuit 12-3 comprises a pad unit 30, a voltage generator 123, an interface circuit 124, and others.

The pad unit 30 comprises a DQ pad (data pad) 30-1, a DQS pad 30-2, a VDDQ pad 30-3, and others. The DQ pad 30-1 inputs the data from the outside, and outputs the data to the outside. The DQS pad 30-2 inputs a data strobe signal from the outside, and outputs the data strobe signal to the outside. The VDDQ pad 30-3 receives a power supply VDDQ for a circuit, which perform a data input/output operation, from the outside.

The peripheral circuits 12-2, 12-4 and 12-5 shown in FIG. 1 comprise interconnections electrically connecting the peripheral circuits 12-1 and 12-3, interconnections electrically connecting the peripheral circuits 12-1 and 12-3 to each bank, and others.

[1-3] Configuration of the Memory Cell Array

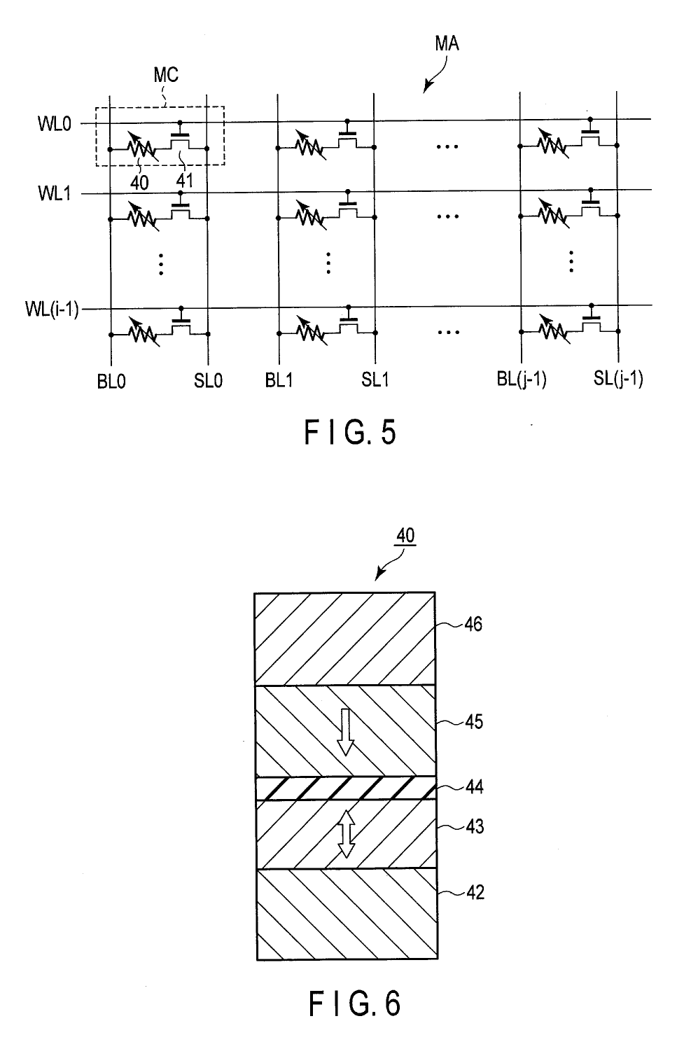

Next, an example of the configuration of the memory cell array 101 included in the bank 100 is described. FIG. 5 is a circuit diagram of the memory cell array 101.

The memory cell array MA comprises a plurality of memory cells MC arranged in a matrix pattern. In the memory cell array MA, a number i of word lines WL0 to WL(i−1) are provided, and a number j of bit lines BL0 to BL(j−1) are provided. One word line WL is connected to one row of the memory cells MA. A pair of one bit line BL and one source line SL is connected to one column of the memory cells MA.

Memory cell MC comprises a magnetic tunnel junction (MTJ) element 40 and a selection transistor 41. The selection transistor 41 comprises, for example, an N-channel MOS transistor.

The MTJ element 40 is connected at one side to a bit line BL, and at another side to the drain of the selection transistor 41. The gate of the selection transistor 41 is connected to the word line WL. The source of the selection transistor 41 is connected to the source line SL.

[1-4] Structure of the MTJ Element 40

Next, an example of the structure of the MTJ element 40 is described. FIG. 6 is a sectional view of an MTJ element 40. The MTJ element 40 comprises a lower electrode 42, a memory layer (free layer) 43, a non-magnetic layer (tunnel barrier layer) 44, a reference layer (fixed layer) 45, and an upper electrode 46, stacking in this order. The memory layer 43 and the reference layer 45 may be switched in the order they are stacked.

The memory layer 43 and reference layer 45 are made of a ferromagnetic material. The tunnel barrier layer 44 is made of an insulating material such as MgO.

The memory layer 43 and reference layer 45 comprise a magnetic anisotropy in, for example, the vertical direction, and the direction of easy magnetization of the memory layer 43 and reference layer 45 is the vertical direction. Incidentally, the magnetization direction of the memory layer 43 and reference layer 45 may be an in-plane direction.

The magnetization direction of the memory layer 43 is variable (reversible). The magnetization direction of the reference layer 45 is invariable (fixed). The reference layer 45 is set comprising more vertical anisotropy energy than that of the memory layer 43. The reference layer 45 is set to have a sufficiently greater vertical magnetic anisotropy energy than the memory layer 43. The setting of the magnetic anisotropy is enabled by adjusting the material composition or the film thickness. In this manner, the magnetization reversal current of the memory layer 43 is set to be small, and the magnetization reversal current of the reference layer 45 is set to be larger than that of the memory layer 43. Thereby, the MTJ element 40 is realized, which comprises the memory layer 43 with the magnetization direction that can be varied by a predetermined write current, and the reference layer 45 with the magnetization direction that cannot be varied by the predetermined write current.

In the present embodiment, use is made of a spin-transfer writing method in which a write current is caused to directly flow in the MTJ element 40, and the state of magnetization of the MTJ element 40 is controlled by this write current. The MTJ element 40 can take either a low resistance state or a high resistance state, depending on whether the relative relationship of magnetization between the memory layer 43 and reference layer 45 is parallel or antiparallel.

If a write current in a direction from the memory layer 43 toward the reference layer 45 is caused to flow in the MTJ element 40, the relative relationship of magnetization between the memory layer 43 and reference layer 45 becomes parallel. In the case of this parallel state, the resistance value of the MTJ element 40 becomes lowest, and the MTJ element 40 is set in the low resistance state. The low resistance state of the MTJ element 40 is defined, for example, as data “0”.

On the other hand, if a write current in a direction from the reference layer 45 toward the memory layer 43 is caused to flow in the MTJ element 40, the relative relationship of magnetization between the memory layer 43 and reference layer 45 becomes antiparallel. In the case of this antiparallel state, the resistance value of the MTJ element 40 becomes highest, and the MTJ element 40 is set in the high resistance state. The high resistance state of the MTJ element 40 is defined, for example, as data “1”.

Thereby, the MTJ element 40 can be used as a memory element which can store 1-bit data (2-value data). The assignment between the resistance state and data of the MTJ element 40 can arbitrarily be set.

When data is read out of the MTJ element 40, a read voltage is applied to the MTJ element 40, and a resistance value of the MTJ element 40 is detected based on the read current flowing in the MTJ element 40 at this time. This read voltage is set at a sufficiently lower value that the threshold of magnetization reversal by spin transfer.

### [2] Configuration of the ZQ Calibration Circuit 21

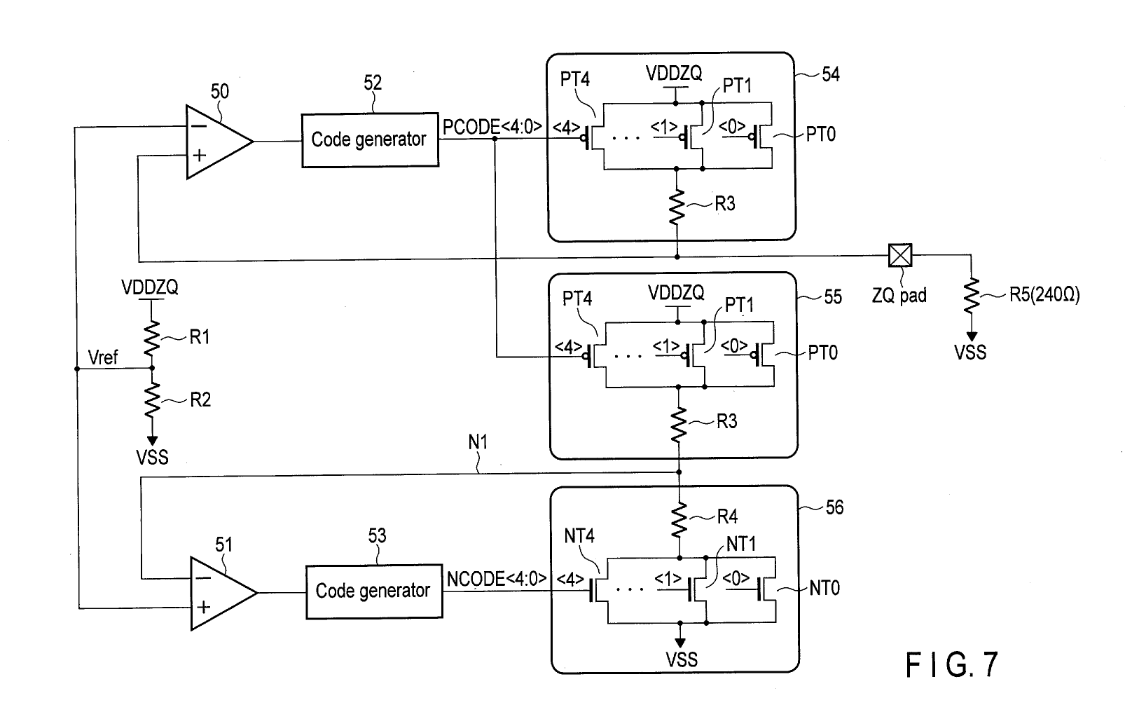

Next, an example of the configuration of the ZQ calibration circuit 21 shown in FIG. 3 is described. FIG. 7 is a circuit diagram of the ZQ calibration circuit 21. The ZQ calibration circuit 21 comprises comparators 50 and 51, code generators 52 and 53, replica pull-up units 54 and 55, and a replica pull-down unit 56.

The positive-input terminal of the comparator 50 is connected to a ZQ pad. The negative-input terminal of the comparator 50 is applied with reference voltage Vref. The reference voltage Vref is generated by using resistors R1 and R2. The resistors R1 and R2 are connected in series between a power supply (power-supply voltage source) VDDZQ and another power supply (ground voltage source) VSS. The resistors R1 and R2 have the same resistance (e.g., 2 kΩ), namely R1=R2. The reference voltage Vref is set to VDDZQ/2. The comparator 50 compares the voltage at the positive-input terminal with the voltage at the negative-input terminal.

The code generator 52 receives the comparison result of the comparator 50 and generates a code PCODE<4:0> from the comparison result of the comparator 50. The code PCODE<4:0> is composed of, for example, 5-bit data. The code generator 52 is composed of an up/down counter and a register. The up/down counter counts the comparison result of the comparator 50. The register holds the output of the up/down counter. The code PCODE<4:0> is supplied to the replica pull-up units 54 and 55.

The replica pull-up units 54 and 55 are replicas of the pull-up unit included in the output driver connected to the DQ pad. Each of the replica pull-up units 54 and 55 comprises five P-channel MOS transistors PT0 to PT4 and a resistor R3. The number of transistors PT0 to PT4 provided is equal to the number of bits that constitute the code PCODE<4:0>. The transistors PT0 to PT4 are connected in parallel between the power supply VDDZQ and one end of the resistor R3. The codes PCODE<0> to PCODE<4> are supplied to gates of the transistors PT0 to PT4, respectively, from the code generator 52. The other end of the resistor R3 is connected to the ZQ pad. The replica pull-up unit 55 is connected to an output node N1.

The transistors PT0 to PT4 are configured with different sizes (thus having different on-resistances). The code PCODE<4:0> output from the code generator 52 is used to select any one of the transistors PT0 to PT4 having different sizes. The resistance of the resistor R3 is set to such a value that the sum of the resistance thereof and the on-resistance of one transistor PT may become about 240Ω, and is, for example, about 20Ω.

The reference voltage Vref is applied to the positive-input terminal of the comparator 51. The negative-input terminal of the comparator 50 is connected to the output node N1. The comparator 51 compares the voltage at the positive-input terminal with the voltage at the negative-input terminal.

The code generator 53 receives the comparison result of the comparator 51 and generates a code NCODE<4:0> from the comparison result of the comparator 51. Like the code generator 52, the code generator 53 is composed of an up/down counter and a resistor. The code NCODE<4:0> is supplied to the replica pull-down unit 56.

The replica pull-down unit 56 is a replica of the pull-down unit included in the output driver connected to the DQ pad. The replica pull-down unit 56 comprises five N-channel MOS transistors NT0 to NT4 and a resistor R4. The number of transistors NT0 to NT4 corresponds to the number of bits that constitute the code NCODE<4:0>. One end of the resistor R4 is connected to the output node N1. The transistors NT0 to NT4 are connected in parallel between the other end of the resistor R4 and the power supply VSS. The codes NCODE<0> to NCODE<4> are supplied to gates of the transistors NT0 to NT4, respectively, from the code generator 53.

The transistors NT0 to NT4 are configured with different sizes (thus having different on-resistances). The code NCODE<4.0> output from the code generator 53 is used to select one of the transistors NT0 to NT4 having different sizes. The resistance of the resistor R4 is set to such a value that the sum of the resistance thereof and the on-resistances of one transistor NT is about 240Ω, and is, for example, about 20Ω.

The ZQ calibration circuit 21 operates by using the power supply VDDZQ dedicated to it. As shown in FIG. 3, the power supply VDDZQ is supplied to the semiconductor memory device 10 through the VDDZQ pad 20-4. That is, the ZQ calibration circuit 21 is provided in the VDDZQ domain. The semiconductor memory device 10 may receive the power supply VDD and may generate the power supply VDDZQ dedicated to the ZQ calibration circuit 21 by using the power supply VDD in the inside. Not only the power supply VDD, but also the power supply VSS may be isolated and dedicated to the ZQ calibration circuit 21.

Next, the operation of the ZQ calibration circuit 21 configured as shown above is described. A reference resistor R5 is connected between the ZQ pad and the power supply VSS. The resistor R5 is connected to the outside of the semiconductor chip. The resistance of the reference resistor R5 is, for example, 240Ω.

First, the calibration is performed at the pull-up side, generating a code PCODE<4:0> for the pull-up side. That is, the code generator 52 counts up or down the code PCODE<4:0> until the voltage at the ZQ pad becomes almost the same as the reference voltage Vref. The replica pull-up unit 54 turns on the transistor PT selected in accordance with the code PCODE<4:0>. Thereby, the voltage at the ZQ pad is adjusted, and the code PCODE<4:0> is generated when the voltage at the ZQ pad becomes almost equal to the reference voltage Vref.

Then, the calibration is performed at the pull-down side, generating a code NCODE<4:0> for the pull-down side. The resistance of the output node N1 at the pull-up side has already been set by the replica pull-up unit 55. The code generator 53 counts up or down the code NCODE<4:0> until the voltage at the output node N1 becomes almost the same as the reference voltage Vref. The replica pull-down unit 56 turns on the transistor NT selected in accordance with the code NCODE<4:0>. Thereby, the voltage at the output node N1 is adjusted, and the code NCODE<4:0> is generated when the voltage at the node N1 becomes almost equal to the reference voltage Vref.

The code PCODE<4:0> and the code N CODE<4:0>, thus generated, are supplied to the output driver connected to the DQ pad. The output impedance of the output driver is set on the basis of the codes PCODE<4:0> and N CODE<4:0>.

### [3] Configuration of the Output Driver

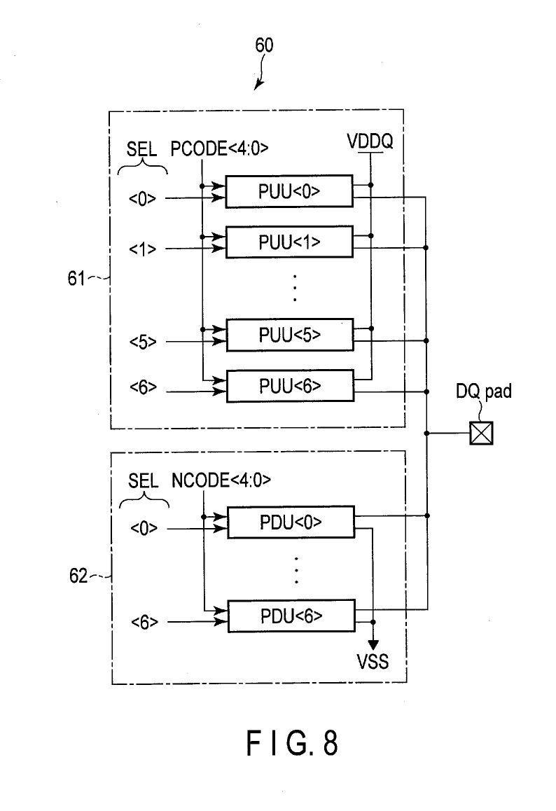

Next, an example of the configuration of the output driver 60 is described. The output driver 60 is connected to the DQ pad. FIG. 8 is a block diagram of the output driver 60. FIG. 8 shows one DQ pad and the output driver connected to the DQ pad. In practice, a plurality of DQ pads are provided, and a plurality of output drivers are provided, which are connected to the DQ pads, respectively.

The output driver 60 comprises a pull-up circuit 61 and a pull-down circuit 62. The pull-up circuit 61 comprises a plurality of pull-up units PUU<0> to PUU<6>. The pull-up units PUU<0> to PUU<6> are identical in configuration to the replica pull-up unit 55 shown in FIG. 7. The code PCODE<4:0> is input to the pull-up units PUU<0> to PUU<6>, and the transistor PT corresponding to an activated bit of the code PCODE<4:0> is turned on. The power supply VDDQ is supplied to the pull-up units PUU<0> to PUU<6>. The pull-up units PUU<0> to PUU<6> are connected parallel to the DQ pad. Selection signals SEL<0> to SEL<6> is input to the pull-up units PUU<0> to PUU<6>, respectively.

Similarly, the pull-down circuit 62 comprises a plurality of pull-up units PDU<0> to PDU<6>. The pull-down units PDU<0> to PDU<6> are identical in configuration to the replica pull-down unit 56 shown in FIG. 7. The code NCODE<4:0> is input to the pull-down units PDU<0> to PDU<6>, and the transistors NT corresponding to an activated bit of the code NCODE<4:0> is turned on. The pull-down units PDU<0> to PDU<6> are connected parallel to the DQ pad. The power supply VSS is supplied to the pull-down units PDU<0> to PDU<6>. Selection signals SEL<0> to SEL<6> are input to the pull-down units PDU<0> to PDU<6>, respectively.

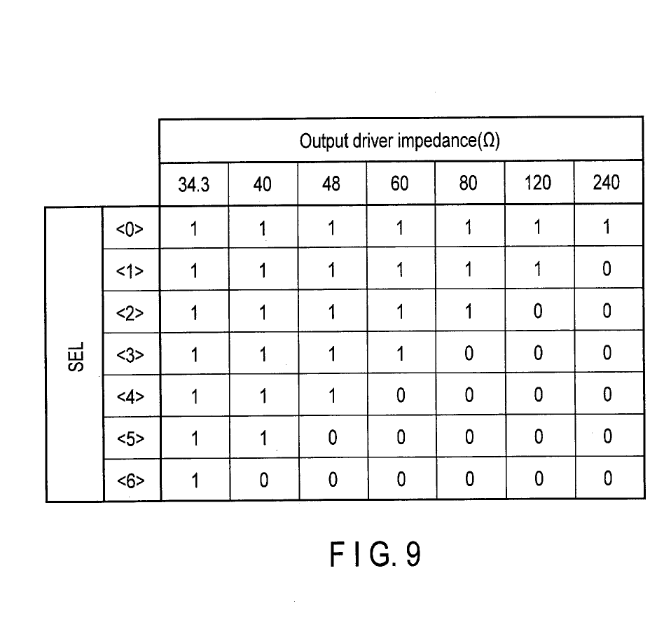

FIG. 9 is a diagram illustrating the relation between the output impedance of the output driver 60 and the selection signal <6:0>. The output impedance of the output driver 60 can be set to any one of seven values in response to the selection signal <6:0>. The output impedance so set adjusts the drive strength of the output driver 60.

Assume that selection signal SEL<0>, for example, is asserted. Then, the pull-up unit PUU<0> and the pull-down unit PDU<0> are connected to the DQ pad. As a result, the output impedance of the DQ pad is set to 240Ω. If the selection signals SEL<0> and SEL<1> are asserted, the pull-up unit PUU<0>, pull-up unit PUU<1>, pull-down unit PDU<0>, and pull-down unit PDU<1> are connected to the DQ pad. As a result, the output impedance of the DQ pad is set to 120Ω. The selection signal SEL is set by, for example, the user.

### [4] Operation

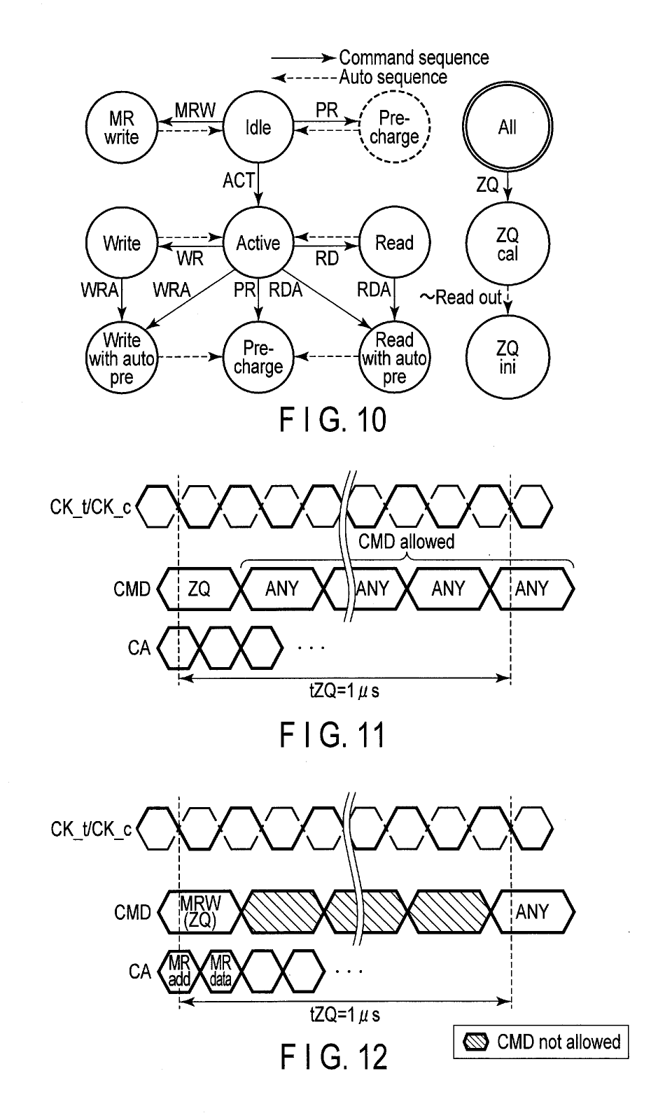

Next, the operation of the semiconductor memory device 10 is described. FIG. 10 is a state diagram of the semiconductor memory device 10.

The control circuit 108 performs, in response to a command from the outside, a write operation for writing data to the bank, and a read operation for reading data from the bank. In FIG. 10, MRW=mode register write, PR=precharge, ACT=active, WR=write, RD=read, WRA=write with auto-precharge, RDA=read with auto-precharge, ZQ cal=ZQ calibration, and ZQ ini=ZQ initialization. The ZQ calibration is an operation for generating the codes PCODE<4:0> and NCODE<4:0> by using by using the ZQ pad. The ZQ initialization is an operation for setting the output impedance of the output driver 60 connected to the DQ pad by using the codes PCODE<4:0> and NCODE<4:0>. In FIG. 10, solid-line arrows indicate the command sequence, and the broken-line arrows indicate the automatic sequence.

FIG. 11 is a timing chart of the ZQ calibration operation. In FIG. 11, clocks CK_t and CK_c are complementary clock signals. CMD is a command, and CA is the address and data received from a CA pad. tZQ is the time from the receipt of the ZQ calibration command to the end of the ZQ calibration operation (including the ZQ initialization), and is about 1 μs in the embodiment.

In the embodiment, a ZQ calibration command is newly defined, which demands that ZQ calibration operation should be performed. Namely, a dedicated ZQ calibration command is provided. The control circuit 108 receives the ZQ calibration command from the outside. In response to the ZQ calibration command, the ZQ calibration circuit 21 and control circuit 108 perform the ZQ calibration.

So configured in both system and specification, the control circuit 108 and bank manager 122 can receive any commands while they are performing the ZQ calibration. In other words, as seen from the status diagram of FIG. 10, the control circuit 108 and bank manager 122 can receive the ZQ calibration command and perform the ZQ calibration operation even while operating in accordance with any other commands. For example, as evident from the status diagram of FIG. 10, the control circuit 108 and bank manager 122 can receive the ZQ calibration command while the semiconductor memory device 10 is an active state and while the write operation is performed.

The output impedance of the output driver 60 connected to the DQ pad is adjusted during the ZQ calibration. Therefore, an operation for outputting read data by using the DQ pad is limited during the ZQ calibration operation. This condition may be seen from “˜Read out” shown in FIG. 10. The limitation of the data output is controlled by the code generator 52 shown in FIG. 7, or by the pull-up circuit 61 and pull-down circuit 62, both shown in FIG. 8.

### Comparative Example

Next, the ZQ calibration operation of a comparative example is described. FIG. 12 is a timing chart of the ZQ calibration performed in the comparative example.

In the comparative example, the ZQ calibration operation is incorporated in the mode register write operation. The mode register write operation is performed at least when the semiconductor memory device 10 is started (powered on).

The control circuit 108 and bank manager 122 receive a mode register write (MRW) command, a mode register address, and mode register data from the outside. The MRW command is used to write configuration data to the mode register.

Subsequently, the ZQ calibration circuit 21 performs a ZQ calibration operation in response to the MRW command. Time tZQ is a period from the receipt of the MRW command to the end of both the mode register write operation and the ZQ calibration operation, and is about 1 μs in the comparative example.

In the comparative example, the ZQ calibration is performed every time the MRW command is received. According to the specification of the comparative example, neither the control circuit 108 nor the bank manager 122 can receive any command for time tZQ.

### [5] Advantageous Effects

As has been described, the semiconductor memory device 10 according to the embodiment comprises the ZQ calibration circuit 21 configured to adjust the output impedance of the output driver connected to the DQ pad. The dedicated ZQ calibration command is provided for instructing the ZQ calibration operation by the ZQ calibration circuit 21. The control circuit 108 and bank manager 122 perform the ZQ calibration operation when receiving the ZQ calibration command.

According to the embodiment, the ZQ calibration operation can be performed at any time.

In the comparative example, the mode register write incorporates the ZQ calibration. Therefore, the ZQ calibration is frequently performed in the device which is powered down frequently. In this case, the ability of the device is degraded. For example, if the device is used at high frequency, the ZQ calibration will be performed long in the comparative example. In the embodiment, the timing of the ZQ calibration can be controlled in accordance with the use condition of the system incorporating the semiconductor memory device 10. Therefore, the ZQ calibration can be performed in accordance with the use condition of the system, even if the semiconductor memory device 10 is used in various conditions.

The power supply VDDZQ dedicated to the ZQ calibration circuit 21 is provided. Thus, the ZQ calibration circuit 21 is provided in the VDDZQ domain. Therefore, the power supply for the ZQ calibration circuit 21 is isolated, reducing the variation of the power supply VDDZQ. As a result, the ZQ calibration can be more accurate than otherwise.

The MRAM used in the embodiment described above may be a spin-transfer torque magnetoresistive random access memory (STT-MRAM).

Besides, in each of the above-described embodiments, the MRAM using the magnetoresistive effect element has been described as the semiconductor device by way of example, but the embodiments are not limited to this, and are applicable to various kinds of semiconductor memory devices, regardless of volatile memories and nonvolatile memories. In addition, the embodiments are applicable to resistance change type memories similar to the MRAM, such as a resistive random access memory (ReRAM) and a phase-change random access memory (PCRAM).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first pad which outputs data to the outside;
an output driver coupled to the first pad;
a calibration circuit which adjusts impedance of the output driver; and
a controller which
controls a calibration operation by the calibration circuit, in response to a first command received from the outside, and
performs a write operation on a mode resister, in response to a second command received from the outside, the second command being different from the first command.

2. The device of claim 1, wherein the controller is acceptable of any command while the calibration operation is performed.

3. The device of claim 1, wherein the first command is defined separately from the second command.

4. The device of claim 1, wherein the calibration circuit is coupled to a dedicated power supply.

5. The device of claim 1, wherein the calibration circuit is coupled to a power supply different from the output driver.

6. The device of claim 1, wherein
the output driver comprises a pull-up unit coupled between a first power supply and the first pad, and a pull-down unit coupled between the first pad and a second power supply, and
the calibration circuit adjusts impedance of the pull-up unit and impedance of the pull-down unit.

7. The device of claim 6, wherein
the pull-up unit comprises a first resistor and PMOS transistors, the PMOS transistors being connected in parallel between the first power supply and the first resistor, on-resistances of the PMOS transistors being different from each other, and
the pull-down unit comprises a second resistor and NMOS transistors, the NMOS transistors being connected in parallel between the second resistor and the second power supply, on-resistances of the NMOS transistors being different from each other.

8. The device of claim 6, wherein the calibration circuit comprises:
a second pad coupled to a reference resistor;
a first replica pull-up unit coupled to the second pad;
a first comparator which compares a reference voltage with a voltage of the second pad;
a first code generating circuit which adjusts impedance of the first replica pull-up unit in accordance with a comparison result of the first comparator;
a second replica pull-up unit coupled to an output node and set to the same impedance as the first replica pull-up unit;
a replica pull-down unit coupled to the output node;
a second comparator which compares the reference voltage with a voltage of the output node; and
a second code generating circuit which adjusts impedance of the replica pull-down unit in accordance with a comparison result of the second comparator.

9. The device of claim 1, further comprising a memory cell array including magnetoresistive effect elements.

10. The device of claim 1, which is a spin-transfer torque magnetoresistive random access memory (STT-MRAM).
